(19) United States
(12) Patent Application Publication
(10) Pub. No.: US 2023/0010004 A1
(43) Pub. Date: Jan. 12, 2023

(54) Power Semiconductor Device and Method of Producing a Power Semiconductor Device

(71) Applicant: Infineon Technologies AG, Neubiberg (DE)

(72) Inventors: Frank Dieter Pfirsch, Muenchen (DE); Thomas Kuenzig, Baldham (DE)

(21) Appl. No.: 17/859,453

(22) Filed: Jul. 7, 2022

(30) Foreign Application Priority Data
Jul. 9, 2021 (DE) 102021117826.6

(51) Int. Cl. H01L 29/40

(52) U.S. Cl. CPC H01L 29/402; H01L 29/401

(57) ABSTRACT

A power semiconductor device includes an active region and an edge termination region surrounding the active region. A field plate structure arranged around the active region includes at least one electrically conductive track electrically connected to a first potential of a first load terminal at a first joint and, at a second joint, electrically connected to a second potential of a second load terminal. The track forms at least n crossings, wherein n is greater 5, with a straight virtual line that extends from the active region towards an edge of the edge termination region. The difference in potential between adjacent two crossings increases in at least 50% of the length of the virtual line, and/or the difference in potential within, with respect to the active region, the first 20% of the length of virtual line is less than 10% of the total difference in potential along the virtual line.

### TECHNICAL FIELD

This specification refers to embodiments of a power semiconductor device and to embodiments of a method of producing a power semiconductor device. In particular, this specification is related to configurations of an edge termination region of the power semiconductor device and corresponding methods.

### BACKGROUND

Many functions of modern devices in automotive, consumer and industrial applications, such as converting electrical energy and driving an electric motor or an electric machine, rely on power semiconductor switches. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body configured to conduct a forward load current along a load current path between two load terminals of the device.

Further, in case of a controllable power semiconductor device, e.g., a transistor, the load current path may be controlled by means of an insulated electrode, commonly referred to as gate electrode. For example, upon receiving a corresponding control signal from, e.g., a driver unit, the control electrode may set the power semiconductor device in one of a forward conducting state and a blocking state.

The load current is typically conducted by means of an active region of the power semiconductor device. The active region is typically surrounded by an edge termination region, which is terminated by an edge of the chip.

The edge termination region is typically not used for load current conduction purposes, but to safely terminate the active region and guarantee robust blocking characteristics of the device.

At one side of the chip, e.g., the frontside, the electrical potentials of both load terminals may be present, and the edge termination region may provide for electrical path between these electrical potentials. With respect to the primary function of the edge termination region, namely, to safely terminate the active region, it may be desirable to provide for a distinct voltage course between these electrical potentials within the edge termination region.

### SUMMARY

According to the invention, the subject-matter of the independent claims is presented. Features of exemplary embodiments are defined in the dependent claims.

According to an embodiment, a power semiconductor device comprises: an active region configured to conduct a load current between a first load terminal and a second load terminal; an edge termination region surrounding the active region; in the edge termination region, a field plate structure arranged around the active region and comprising at least one electrically conductive track electrically connected to a first potential of the first load terminal at a first joint and, at a second joint, electrically connected to a second potential of the second load terminal. The at least one electrically conductive track forms at least n crossings, wherein n is greater 5, with a straight virtual line that extends from the active region towards an edge of the edge termination region, wherein, e.g., in a forward biased blocking state of the power semiconductor device, the difference in potential between adjacent two of then crossings increases in at least 50% or in at least 60% or in at least 80% of the length of the virtual line, and/or wherein, e.g., in said forward biased blocking state of the power semiconductor device, the difference in potential within, with respect to the active region, the first 20% of the length of virtual line is less than 10% of the total difference in potential along the virtual line.

According to another embodiment, a method of producing a power semiconductor device comprises forming the following components: an active region configured to conduct a load current between a first load terminal and a second load terminal; an edge termination region surrounding the active region; in the edge termination region, a field plate structure arranged around the active region and comprising at least one electrically conductive track electrically connected to a first potential of the first load terminal at a first joint and, at a second joint, electrically connected to a second potential of the second load terminal. The at least one electrically conductive track forms at least n crossings, wherein n is greater 5, with a straight virtual line that extends from the active region towards an edge of the edge termination region, wherein, e.g., in a forward biased blocking state of the power semiconductor device, the difference in potential between adjacent two of the n crossings increases in at least 50%, in at least 60%, or in at least 80% of the length of the virtual line, and/or, e.g., in said forward biased blocking state of the power semiconductor device, wherein the difference in potential within, with respect to the active region, the first 20% of the length of virtual line is less than 10% of the total difference in potential along the virtual line.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIGS. 1-3 each schematically and exemplarily illustrate a section of a horizontal projection of a power semiconductor device in accordance with one or more embodiments;

FIG. 4 illustrates exemplary courses of the electrical potential in an edge termination region of a power semiconductor device in accordance with some embodiments;

FIGS. 5-6 both schematically and exemplarily illustrate a section of a vertical cross-section of a power semiconductor device in accordance with one or more embodiments;

FIGS. 7-9 each schematically and exemplarily illustrate a section of a horizontal projection of a power semiconductor device in accordance with one or more embodiments;

FIGS. 10-11 each illustrate exemplary courses of the electrical potential and the resistance in an edge termination region of a power semiconductor device in accordance with one or more embodiments;

FIGS. 12-14 each schematically and exemplarily illustrate a section of a horizontal projection of a power semiconductor device in accordance with one or more embodiments;

FIGS. 15-16 both schematically and exemplarily illustrate a section of a vertical cross-section of a power semiconductor device in accordance with one or more embodiments;

FIG. 17 schematically and exemplarily illustrates a representation of an edge termination region of a power semiconductor device in accordance with one or more embodiments; and

FIGS. 18-24 each schematically and exemplarily illustrate a section of a horizontal projection of a power semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled. To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device, e.g., a power semiconductor device that may be used within a power converter or a power supply. Thus, in an embodiment, such device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell (e.g., a monolithically integrated cell of two anti-serially connected diodes), a monolithically integrated transistor cell, e.g., a monolithically integrated MOSFET or IGBT cell and/or derivatives thereof. Such diode/transistor cells may be integrated in a power semiconductor module. A plurality of such cells may constitute a cell field that is arranged with an active region of the power semiconductor device.

The term “blocking state” of the power semiconductor device may refer to conditions, when the semiconductor device is in a state configured for blocking a current flow through the semiconductor device, while an external voltage is applied. More particularly, the semiconductor device may be configured for blocking a forward current through the semiconductor device while a forward voltage bias is applied. In comparison, the semiconductor may be configured for conducting a forward current in a “conducting state” of the semiconductor device, when a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the device. The term “forward biased blocking state” therefore may refer to conditions with the semiconductor device being in the blocking state while a forward voltage bias is applied.

The term “power semiconductor device” as used in this specification intends to describe a semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor based data processing.

The present specification in particular relates to a power semiconductor device embodied as a diode, a MOSFET or IGBT, i.e., a unipolar or bipolar power semiconductor transistor or diode or a derivate thereof.

For example, the power semiconductor device described below may be a single semiconductor chip, e.g., exhibiting a stripe cell configuration (or a cellular/needle cell configuration) and can be configured to be employed as a power component in a low-, medium- and/or high voltage application. However, the herein proposed technical teaching may also be applied to a power semiconductor device having a cellular/needle cell configuration.

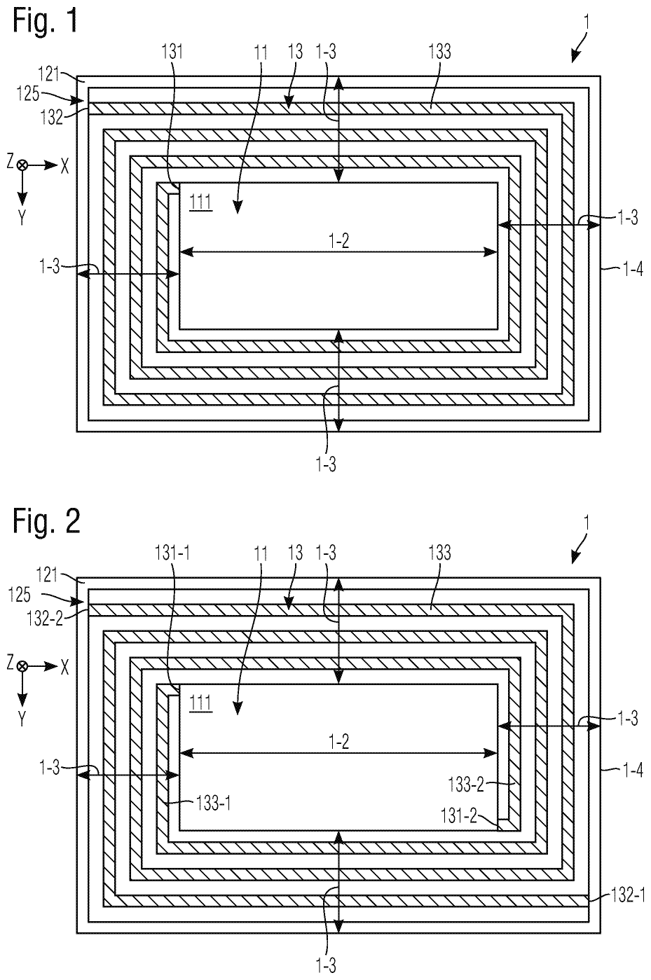

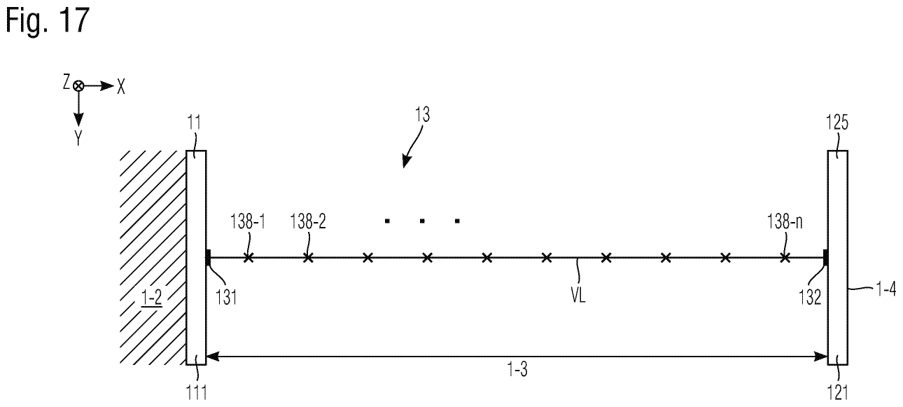

FIGS. 1-3 each schematically and exemplarily illustrate a section of a horizontal projection of a power semiconductor device 1 in accordance with one or more embodiments. In the following, it will be generally referred to each of FIGS. 1-3, wherein each of these Figures will be specially described further below. It is also referred to FIG. 17.

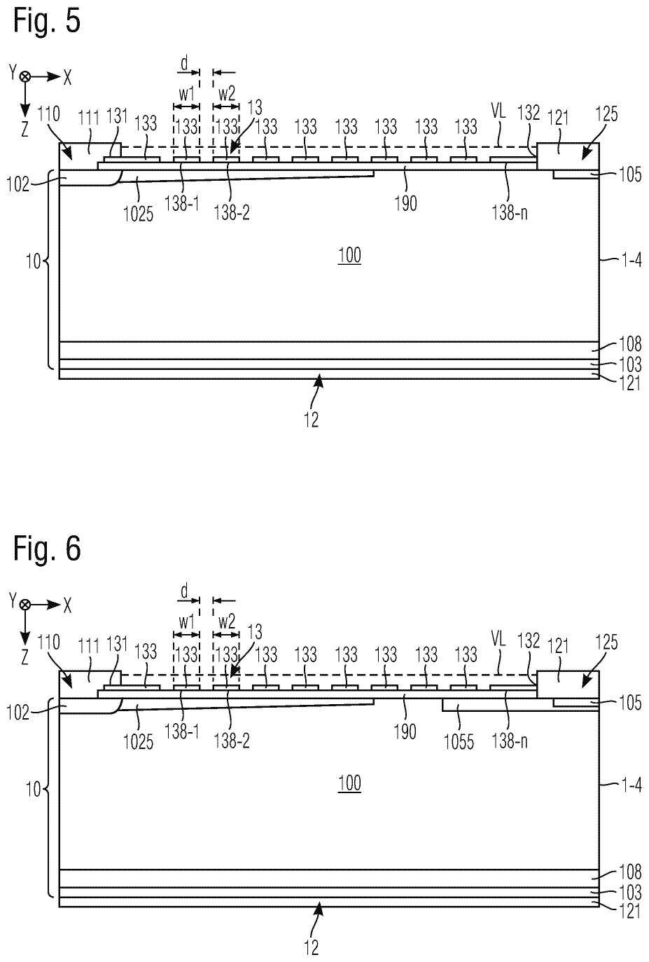

In accordance with the illustrated embodiments, the power semiconductor device 1, herein also referred to as device 1, comprises an active region 1-2 configured to conduct a load current between a first load terminal 11 and a second load terminal 12 (cf. FIG. 5, for example). The first load terminal 11 may be arranged at a frontside of the device 1, and the second load terminal 12 may be arranged at a backside of the device 1. Depending on the configuration of the device 1 (e.g., diode, MOSFET, IGBT or the like), the first load terminal 11 may be an anode terminal, a source terminal or an emitter terminal, and the second load terminal 12 may be a cathode terminal, a drain terminal or a collector terminal. The active region 1-2 may be designed in accordance with the configuration of the device 1 (e.g., diode, MOSFET, IGBT or the like), examples of which being described further below.

An edge termination region 1-3 surrounds the active region 1-2.

As used herein, the terms “edge termination region” and “active region” are both associated with the respective technical meaning the skilled person typically associates therewith in the context of power semiconductor devices. That is, the active region 1-2 is primarily configured for load current conduction and (if applicable) switching purposes, whereas the edge termination region 1-3 primarily fulfills functions regarding reliable blocking capabilities, appropriate guidance of the electric field, sometimes also charge carrier drainage functions, and/or further functions regarding protection and proper termination of the active region 1-2

In the edge termination region 1-3, a field plate structure 13 is arranged around the active region 1-2 and comprises at least one electrically conductive track 133 electrically connected to a first potential 111 of the first load terminal 11 at a first joint 131 and, at a second joint 132, electrically connected to a second potential 121 of the second load terminal 12. Both the first joint 131 and the second joint 132 may be arranged at the frontside 110 of the device 1; that is, based on the field plate structure 13, a connection between the first potential 111 and the second potential 121 may be established at the frontside 110.

Now also referring to FIG. 17, the at least one electrically conductive track 133 forms at least n crossings 138-1, . . . , 138-n, wherein n is greater 5, with a straight virtual line VL that extends from the active region 1-2 towards an edge 1-4 of the edge termination region 1-3. The edge 1-4 may be a chip edge 1-4 that came into being, e.g. based on wafer dicing. The straight virtual line VL may extend perpendicular to the edge 1-4.

The first potential 111 may be provided by a portion of the first load terminal 11, and the second potential 121 may be provided by a contact 125, e.g., arranged at the front side 110. The first potential 111 may, e.g., be the ground/mass potential (e.g., 0 V), and the second potential 121 may, e.g., be a high potential (depending on the state of the power semiconductor device 1, or, respectively, the applied voltage), e.g., greater than 100 V, than 1000 V or even greater than several kV.

In contrast to the schematic representation in FIG. 17, the first and second joints 131 and 132 need not necessarily terminate the virtual line VL. The at least one electrically conductive track 133 may several times surround the active region 1-2, thereby forming the n crossings 138-1, . . . , 138-n with the virtual line VL. E.g., the at least one electrically conductive track 133 may thereby define a coil-shaped field plate structure 13.

In an embodiment, the number of crossings n is greater than 5, e.g., greater than 10, 20, or even greater than 50 or greater than 80.

Based on the at least one electrically conductive track 133 of the field plate structure 13, a defined difference in potential may be ensured within the edge termination region 1-3.

In an embodiment, at least one of the following conditions (i) and (ii) applies, e.g., in a forward biased blocking state of the power semiconductor device (1): (i) The difference in potential between adjacent two of the n crossings 138-1, . . . , 138-n increases in at least 50% or in at least 60% or even in at least 80% of the length of the virtual line VL, (ii) the difference in potential within, with respect to the active region 1-2, the first 20% of the length of virtual line (VL) is less than 10% of the total difference in potential along the virtual line VL.

Thereby, the difference in potential in proximity to the active region 1-2 may be limited to a specific extent, which may contribute to achieving a very high breakdown voltage of the device 1 and is able follow quick changes of the applied voltage (i.e., the difference between the first potential 111 and the second potential 121) immediately. For example, the breakdown voltage can furthermore be insensitive to outer charges since the course of the electrical potential across the edge termination region 1-3 is configured by the distribution of the resistance of the at least one electrically conductive track 133 of the field plate structure 13. Outer charges can be compensated by mirror charges on the field plate structure 13 with the opposite sign.

Many possible structural implementations of the field plate structure 13 with the at least one electrically conductive track 133 are possible for achieving such voltage course, as will be described in more detail below. Before the description of exemplary structural implementations, further examples of the voltage course in the edge termination region 1-3 will be described.

In an embodiment, the difference in potential within, with respect to the active region 1-2, the first 20% of the length of the virtual line VL (that is, in FIG. 17, the left most 20% of the virtual line VL) is less than half of the difference in potential within the last 20% of the length of the virtual line VL (that is, in FIG. 17, the right most 20% of the virtual line VL). Thus, the difference in potential is increased towards the edge 1-4.

But, the difference in potential may also be limited close to the edge 1-4. E.g., both the difference in potential within, with respect to the active region 1-2, the first 20% of the length of the virtual line VL, and the difference in potential within, with respect to the active region 1-2, the last 20% of the length of the virtual line VL, are less than the difference in potential within another 20% of the length of the virtual line VL between the first 20% and the last 20% of the virtual line VL.

For example, FIG. 4 illustrates exemplary courses of the electrical potential in the edge termination region 1-3 of the device 1 in accordance with some embodiments. For example looking at a the vertical line VL from the active area 1-2 to the edge 1-4 in a state with applied blocking voltage, the electric potential is a piecewise constant (namely along the width of the at least one track 133) and in between two adjacent portions of the track 133 an increasing function of the distance to the active area 1-2. In FIG. 4, three examples of such functions are shown, where, e.g., the active region 1-2 ends at position 1000 μm. The dashed line (upper one) corresponds to a linear function (on a coarse scale) which may result from a constant resistance per length of the at least one track 133. The dotted line (middle one) has a slope at the beginning that is only half of the slope at the end of the edge termination region 1-3. The continuous line is an even more extreme case of an inhomogeneous slope (it corresponds to a quadratic function). Simulations have shown that a potential distribution corresponding to the continuous line gives a higher breakdown voltage than for the dotted line, and the dotted line gives a higher breakdown voltage than the dashed line.

For example, in order to achieve the desired voltage course in the termination region 1-3, it may be provided that the ohmic resistance between adjacent two of the n crossings 138-1, . . . , 138-n increases, e.g., monotonously and/or continuously, in at least 50% or in at least 80% of the total length of the virtual line VL. Such embodiment is schematically illustrated in FIG. 10, where there are for example 74 crossings and the resistance (dashed line) between adjacent two of then crossings 138-1, . . . , 138-n increases, e.g., monotonously and/or continuously from the active region 1-2 to the edge 1-4, which is accordingly reflected by the electrical potential (continuous line). In other words, the electric conductivity of the at least one track 133 may decrease, e.g., monotonously and/or continuously, in a portion of the track 133 that forms the crossings 138-1, 138-2, . . . in a portion corresponding to at least 50% of the total length of the virtual line VL.

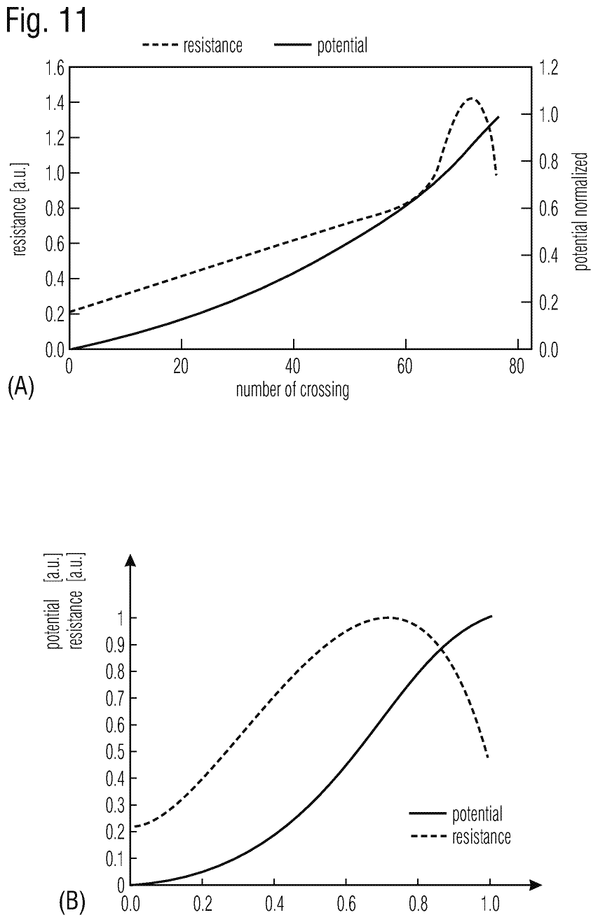

In terms of limiting the voltage difference in proximity to the active region 1-2 and in proximity to the edge 1-4, e.g., in said first 20% and in said last 20% of the virtual line VL, it may be provided that the ohmic resistance between adjacent two of the n crossings 138-1, . . . , 138-n reaches a maximum, e.g., within the last 40% or within the last 20% of the length of the virtual line VL, and from there decreases towards the edge 1-4. Examples of such embodiments are also schematically illustrated in FIG. 11: According to variant (A), where there are for example also 80 crossings and the resistance (dashed line) between adjacent two of the n crossings 138-1, . . . , 138-n increases, until reaching the maximum, in the last 20% of the length of the virtual line VL, and then decreases towards the edge 1-4, which is accordingly reflected by the electrical potential (continuous line). According to variant (B), where the horizontal axis indicates the normalized location coordinates of the crossings along the virtual line VL, the maximum of the resistance (dashed line) is reached earlier, namely in the in the last 40% of the length of the virtual line VL, and then decreases towards the edge 1-4, which is accordingly reflected by the electrical potential (continuous line).

By contrast, in an embodiment, the change in potential along the virtual line VL from the active region 1-2 to the edge 1-4 is not achieved based on the resistance/the electric conductivity that changes, along the extension of a respective crossing (cf. FIG. 5 and FIG. 6, extensions w1 and w2) along the direction of the virtual line VL. For example, the electric conductivity of a respective one of the at least one track 133 along a direction in parallel to the virtual line VL can be substantially constant along the extension of a respective crossing (cf. FIG. 5 and FIG. 6, extensions w1 and w2), e.g., when the field plate structure 13 is coil-shaped.

In the following, some structural features of exemplary embodiments will be explained:

In accordance with the embodiment in FIG. 1, the field plate structure 13 comprises only one track 133 that contiguously extends between the first joint 131 and the second joint 132. For illustrative purposes, only three revolutions of the track 133 around the active region 1-2 are shown, which would result in only n=3 crossings with the virtual line VL (which could for example be located at any of the double-arrows 1-3 in FIG. 1). However, also in accordance with FIG. 1, n is greater 5.

In accordance with the embodiment in FIG. 2, the field plate structure 13 comprises two tracks 133-1 and 133-2 that are arranged in an interleaved configuration and extending from a respective first joint 131-1/131-2 exhibiting the first potential 111 to a respective second joint 132-1/132-2 exhibiting the second potential 112.

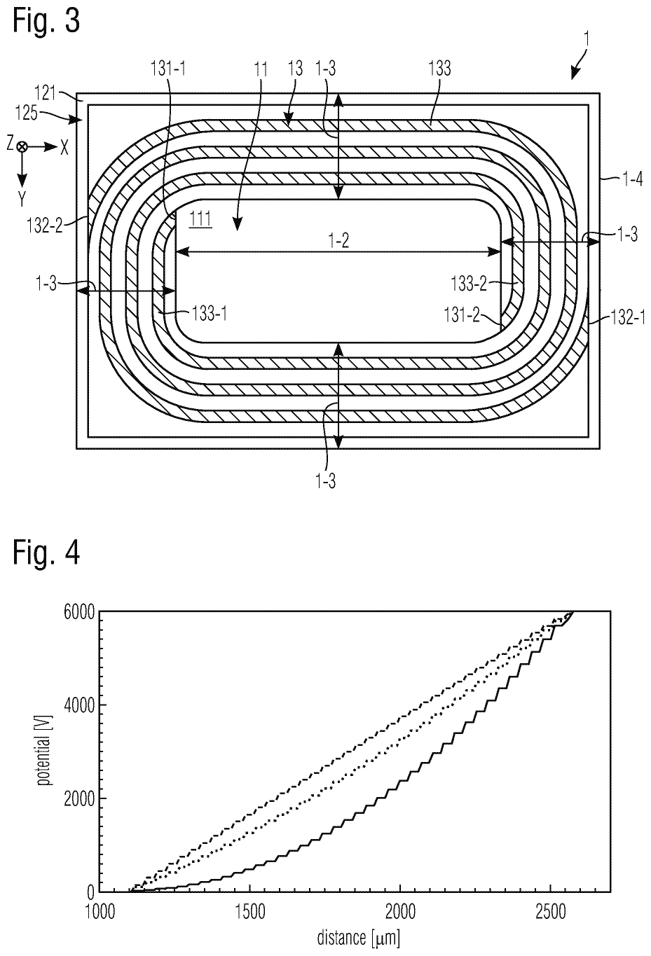

The shape of the track(s) 133, 133-1, 133-2 may be appropriately chosen; for example, instead of a rectangular shape as illustrated in FIG. 1 and in FIG. 2, the tracks 133, 133-1, 133-2 may have ellipsoidal shapes as illustrated in FIG. 3.

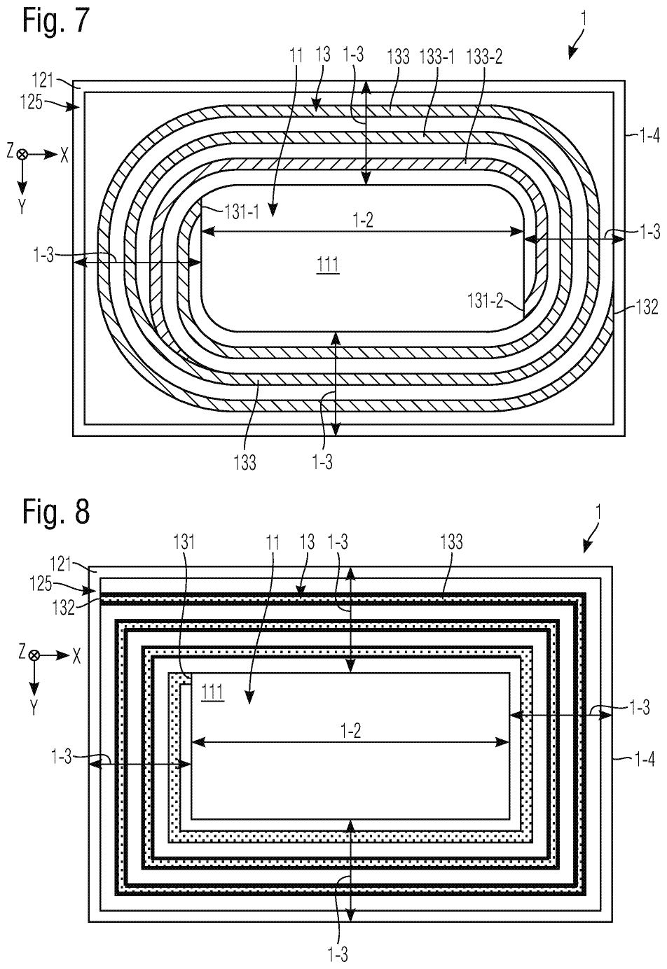

As illustrated in FIG. 7, the two tracks 133-1, 133-2 can also be electrically connected to the first potential 111 of the first load terminal 11 based on separate first joints 131-1, 131-2, and merge into one track (133) in a central portion of the edge termination region.

Referring to FIGS. 5 and 6, a semiconductor body 10 of the device 1 may be sandwiched between the first load terminal and the second load terminal 12. A body or anode region 102 of the second conductivity type can be electrically connected to the first load terminal 11 at the front side 110. The major portion of the semiconductor body 10 may be occupied by a drift region 100 of the first conductivity type. A collector region 103 of the second conductivity type can be electrically connected to the second load terminal 12 at the backside of the device 1. Between the drift region 100 and the collector region 103, there may be a field stop region 108 of the first conductivity type having a greater dopant concentration than the drift region 100. As indicated above, the device 1 can for example be a diode, a MOSFET or an IGBT (or a derivative thereof), which would accordingly be reflected by correspondingly doped regions of the semiconductor body 10. Presently of more interest is the configuration of the edge termination region 1-3, though, in terms of the field plate structure 13 and its at least one track 133. As illustrated in FIGS. 5 and 6, the track 133 may be arranged on an insulation layer 190. A portion of the first load terminal 11 provides the first potential 111 in proximity to the active region 1-2. Said contact 125 provides the second potential 121 of the second load terminal 12 in proximity to the edge 1-4. FIGS. 5 and 6 illustrate n=10 crossings of the track with the virtual line VL.

Still referring to FIGS. 5 and 6, the at least one track 133 has a width along a direction perpendicular to the current pathway of the track 133 from the first joint 131 to the second joint 132, said width defining the extension of the respective crossing 138-1, . . . , 138-n, wherein a distanced between arbitrary two adjacent crossings 138-1, . . . , 138-n along the virtual line VL amounts to at most half of the average of the extensions w1, w2 of the respective adjacent crossings 138-1, . . . , 138-n. That is, the crossings 138-1, . . . , 138-n are comparatively near to each other, such that a correspondingly accurate course of the electrical potential in the edge termination region 1-3 may be achieved. Herein, the term “extension of the crossing”, as illustrated in FIGS. 5 and 6, indicates the distance of the portion of the virtual line VL that overlaps uninterruptible with the track 133. Furthermore, in an embodiment, the average of the distances d between each two adjacent crossings 138-1, . . . , 138-n along the virtual line VL amounts to at most half of the average of the extensions w1, w2 of the respective adjacent crossings 138-1, . . . , 138-n. The respective distances may, however, differ from each other. For example, the distance d between two adjacent crossings 138-1, . . . , 138-n may increase along at least a part of the virtual line VL, e.g., along at least 50% of the total length of the virtual line VL.

Furthermore, the second joint 132 may laterally overlap with a semiconductor well region 105 of the first conductivity type arranged in the semiconductor body 10 of the device 1, and/or the first joint 131 may laterally overlap with the semiconductor body region 102 of the second conductivity type arranged in the semiconductor body 10.

Furthermore, referring to FIG. 6, a first semiconductor region 1055 may extend from the semiconductor well region 105 towards the active region 1-2 and laterally overlap with at least the last crossing 138-n. The first semiconductor region 1055 may have a constant dopant concentration in the first lateral direction X or exhibit a variation-of-the-lateral-doping, VLD, configuration, according to which the dopant concentration decreases towards the active region 1-2. The first semiconductor region 1055 may for example laterally overlap with at least the last 10% of the virtual line VL.

Referring to both FIGS. 5 and 6, a second semiconductor region 1025 may extend from the semiconductor body region 102 towards the edge 1-4 and laterally overlap with at least the 50% of the virtual line VL. Also, the second semiconductor region 1025 can exhibit a variation-of-the-lateral-doping, VLD, configuration, e.g., according to which the dopant concentration decreases toward the edge 1-4. The second semiconductor region 1025 may be electrically connected with the first load terminal 11 via the body region 102 and hence also exhibit the first electrical potential 111. By contrast, the well region 105 may couple the first semiconductor region 1055 to the second electrical potential 121. In an embodiment, the second semiconductor region 1025 may seamlessly adjoin the first semiconductor region 1055; e.g., the second semiconductor region 1025 and the first semiconductor region 1055 need not necessarily be separated from each other (e.g., based on a portion of the drift region 100).

Now referring to FIG. 7, which has already been addressed above, the interleaved configuration of the tracks 133, 133-1 and 133-2 can be such that the density of tracks is modified along the virtual line VL in accordance with the designated voltage course in the edge termination region 1-3.

The geometric configuration of the track 133 of the embodiment illustrated in FIG. 8 corresponds to FIG. 1; here, the tracking comprises an electrical resistance per unit length that varies along the pathway of the track 133 from the first joint 131 to the second joint 132. As with the other embodiments, the first joint 131 is arranged in proximity to the active region 1-2 or, respectively, in/at the active region 1-2, and the second joint 132 is arranged in proximity to the edge 1-4 or, respectively, at the edge 1-4. For example, the electrical resistance per unit length as a minimum in proximity to the first joint 131 and a maximum in proximity to the second joint 132 or somewhere between the first joint 131 and the second joint 132. E.g., such configuration of the track 133 can be achieved based on a corresponding course of a dopant concentration of the track 133, which may be based, e.g., on a poly-crystalline material. In FIG. 8, the decrease of the dopant concentration is illustrated based on the solid lines that increase in width towards the second joint 132.

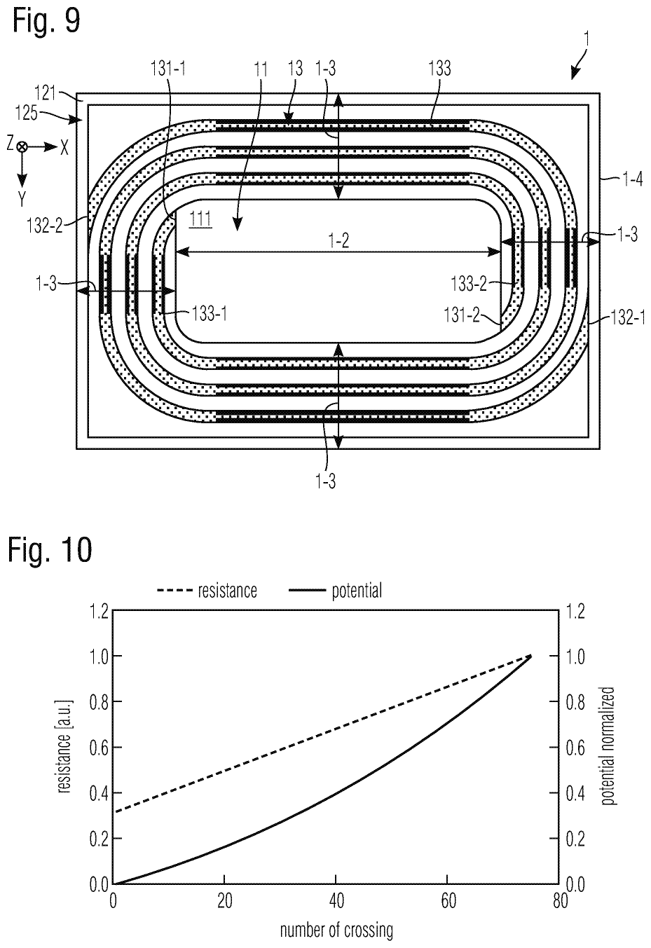

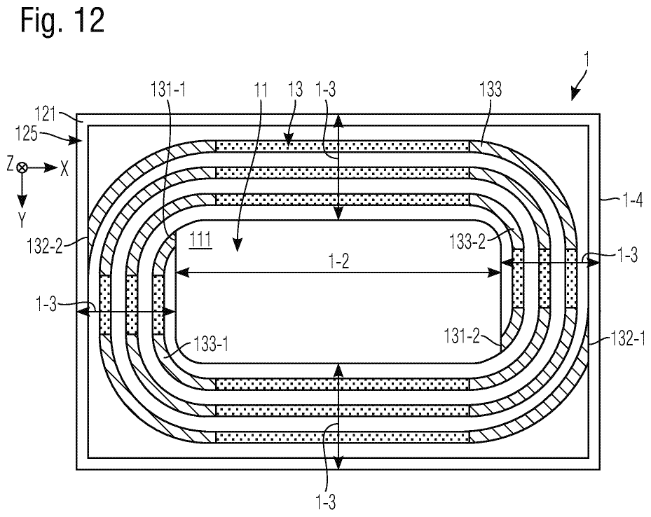

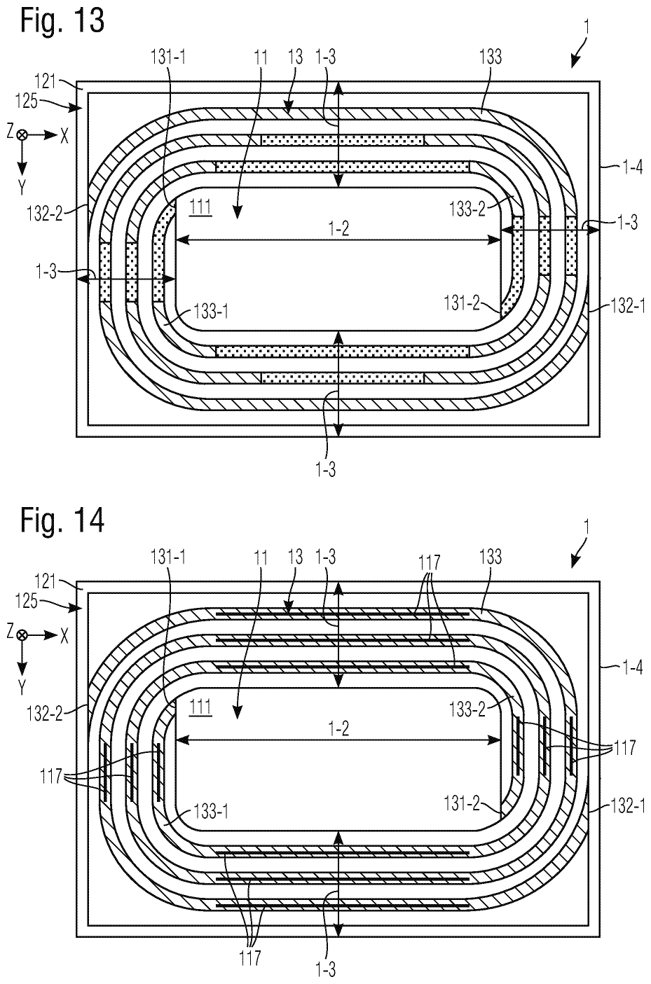

Again, depending on the designated course of the potential in the edge termination region 1-3, many variations of such concept can be implemented. For example, referring to FIG. 9, the dopant concentration is only locally decreased along the pathway of the track 133. Further variations are illustrated in FIGS. 12 and 13, where a high dopant concentration (i.e., low electrical resistance per unit length) in linear portions of the track 133 (dotted areas) and a lower dopant concentration is provided in portions of the track 133 close to chip corners (cross-hatched areas). In other words, referring to FIG. 13, the at least one track 133 comprises at least two first portions (cross-hatched areas) and at least two second portions (dotted areas) which adjoin each other along the pathway of the track 13 from the first joint 131 to the second joint 132, wherein the electrical resistance per unit length of the at least one track 133 has a first value in the first portions and a second value in the second portions.

Of course, the electrical resistance per unit length that varies along the pathway of the track 133 may additionally or alternatively be achieved by other means than a varying dopant concentration, e.g., based on a corresponding variation of the relevant cross-sectional area of the track 133 and/or a variation of the distances d between two adjacent crossings (138-1, . . . , 138-n) or the like.

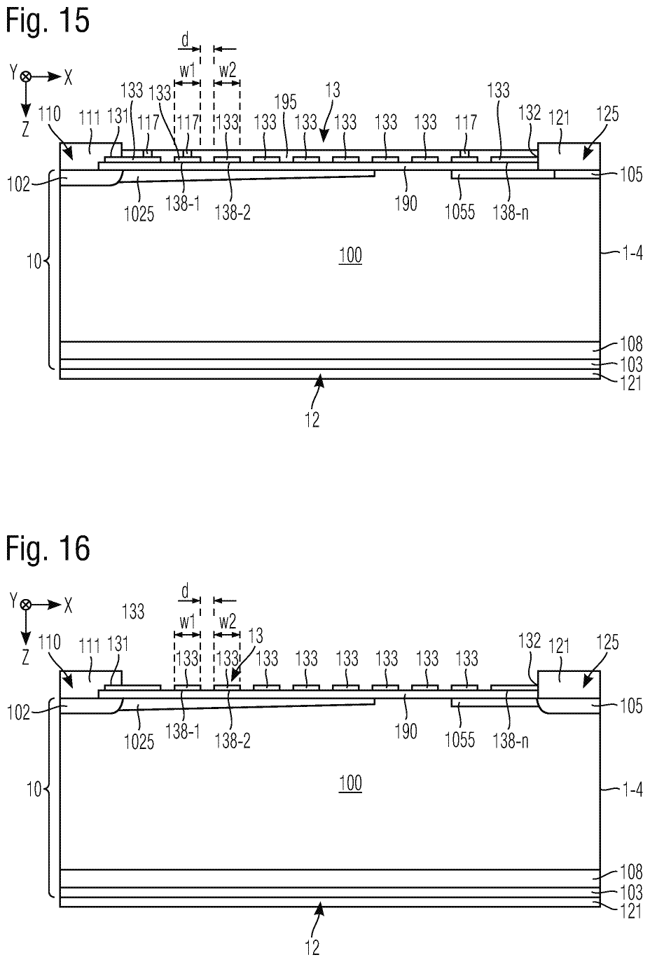

A variation of the relevant cross-sectional area of the track 133 may, for example, be implemented by a variation of the thickness of the track 133 in the vertical direction Z and/or by a variation of the lateral dimension of the track 133, e.g., the extensions w1, w2 of the respective adjacent crossings 138-1, . . . , 138-n. E.g., referring to FIG. 14, based on contact plugs 117, the track 133 may exhibit substantially homogenous dopant concentration, but be locally short-circuited along the pathway in order to achieve the desired course of the electrical potential in the edge termination region 1-3. Such contact plugs 117 are also illustrated in FIG. 15, where a further insulation layer 195 is provided that covers the track 133 and that is penetrated by the contact plugs 117. The contact plugs 117 may be covered by a further insulating layer (not shown).

An example for the variation of the distances d between two adjacent crossings (138-1, . . . , 138-n) is a decrease of the respective distances d between two adjacent crossings (138-1, . . . , 138-n) along at least a part of the virtual line VL, e.g. along at least 50%, at least 60% or at least 80% of the virtual line VL. In other words, a density of the crossings (138-1, . . . , 138-n) may increase along at least a part of the virtual line VL, e.g. along at least 50%, at least 60% or at least 80% of the virtual line VL. Therefore, an increase of the voltage drop during forward biased blocking state conditions along may result from the decreasing distance d along the part of the virtual line VL, or respectively, an increasing density of crossings along the part of the virtual line VL.

The embodiment illustrated in FIG. 16 corresponds to the embodiment of FIG. 6, the only difference being the well region 105 that extends further along the vertical direction Z as compared to the variant of FIG. 6. The well region 105 may server as a (deep) channel stopper contact region.

For example, the at least one track 133 comprises a polycrystalline doped semiconductor material. As described above, the dopant concentration of the polycrystalline doped semiconductor material may vary along the pathway of the track 133 from the first joint 131 to the second joint 132. In another embodiment, the dopant concentration of the polycrystalline doped semiconductor material is substantially constant along the pathway of the track 133 from the first joint 131 to the second joint 132. For example, in the latter variant, the sheet resistance is smaller than 5000 Ω/mm² or smaller than 1000 Ω/mm². Herein, the term “sheet resistance” indicates the specific resistance in two dimensions and may be defined as the inverse of the integrated specific conductivity of the layer, wherein the integral runs along the third (vertical) dimension from the bottom to the top of the layer. The resistance of a rectangular sheet of this layer between to opposite sides of length w is given by the sheet resistance times L/w, where L denotes the length of each of the other two sides of the rectangle.

In a further embodiment, the total resistance measured between the first joint 131 and the second joint 132 is at least 100, or at least 1000 times as great as a lowest sheet resistance of the a material, e.g., a layer material, comprised by the at least one track 133.

In accordance with embodiments described herein, the electrical connection between the first potential 111 and the second potential 121 is not achieved based on a continuous resistive layer covering the edge termination region 1-3, but based on one or more tracks 133 that surround the active region 1-2 at least n times (in whatever manner), wherein the respective windings are spaced apart from each other. For example, in contrast to a substantially continuous layer, the total horizontal area of the at least one track 133 forms at most 75% of the total horizontal area of the edge termination region 1-3.

In accordance with embodiments described herein, each of the one or more tracks 133 may several times surround the active region 1-2. E.g., each of the one or more tracks 133 may extend contiguously around the active region 1-2 for at least three times. If there is only track 133, said track 133 may extend contiguously around the active region 1-2 for at least six times so as to form said n>5 crossings 138-1, . . . , 138-n.

Presented herein is also a method of producing a power semiconductor device, the method comprising forming the following components: an active region configured to conduct a load current between a first load terminal and a second load terminal; an edge termination region surrounding the active region; in the edge termination region, a field plate structure arranged around the active region and comprising at least one electrically conductive track electrically connected to a first potential of the first load terminal at a first joint and, at a second joint, electrically connected to a second potential of the second load terminal. The at least one electrically conductive track forms at least n crossings, wherein n is greater 5, with a straight virtual line that extends from the active region towards an edge of the edge termination region, wherein the difference in potential between adjacent two of the n crossings increases in at least 50% or in at least 60% or even in at least 80% of the length of the virtual line, and/or wherein the difference in potential within, with respect to the active region, the first 20% of the length of virtual line is less than 10% of the total difference in potential along the virtual line.

Embodiments of the method correspond to embodiments of the device 1 above. For example, the varying resistance per unit length may be achieved by a correspondingly masked implantation.

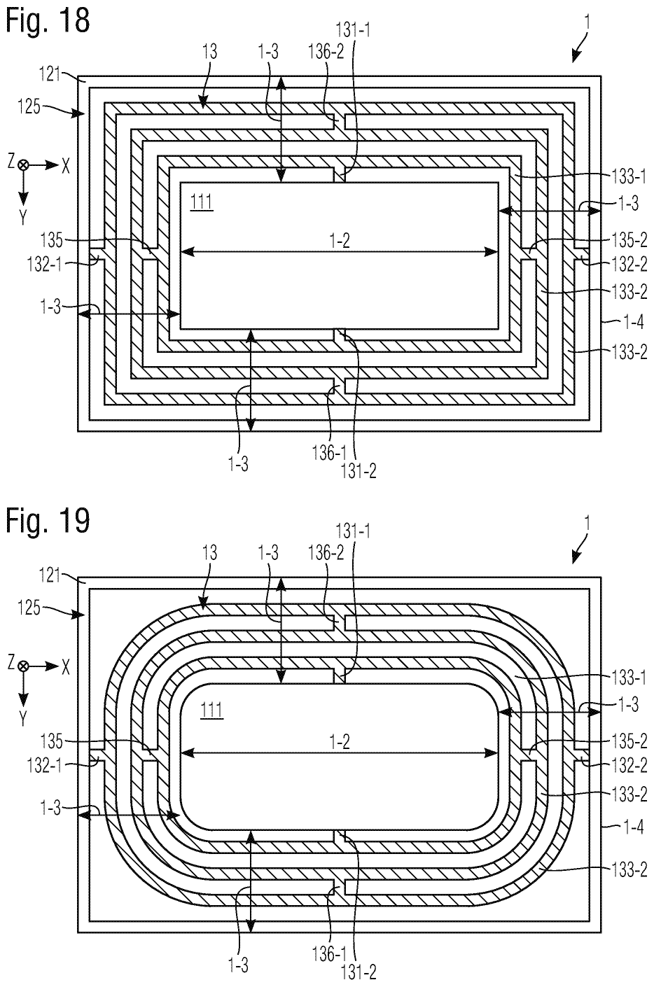

Further embodiments are illustrated in FIGS. 18 to 24. In accordance with these embodiments, the field plate structure 1 is electrically connected to a first potential 111 of the first load terminal 11 and electrically connected to a second potential 121 of the second load terminal 12. Each track 133-1, . . . , 133-n surrounds the active region 1-2. The tracks 133-1, . . . , 133-n are spaced apart from each other along the direction from the active region 1-2 to the edge 1-4. The innermost track 133-1 (i.e., the one closest to the active region 1-2) is electrically connected to the first potential 111 of the first load terminal 11 based on at least two separately arranged first joints 131-1, 131-2. The outermost track 133-n (i.e., the one closest to the edge 1-4) is electrically connected to the second potential 121 of the second load terminal 12 based on at least two separately arranged second joints 132-1, 132-2. Furthermore, the tracks of each pair of adjacent tracks are electrically connected with each other based on at least two separately arranged third joints 135-1, 135-2.

For example, referring to FIG. 18, three tracks 133-1, 133-2 and 133-3 are provided. The second joints 132-1 and 132-2 for electrically connecting the outermost track 133-3 with the second potential 121 are positioned such that the distance between them is maximized. Analogously the first joints 132-1 and 132-2 for electrically connecting the innermost track 133-1 with the first potential 111 are positioned such that the distance between them is maximized. The same applies for the third joints 135-1, 135-2, 136-1 and 136-2 that are employed for electrically connecting the central track 133-2 with the innermost track 133-1 and the outermost track 133-3.

Similar to the above, it shall be understood that the number of tracks can be much higher than 3, e.g., greater than 5, greater than 20, 50 or even greater than 80; however, illustrating such high number of tracks appears inappropriate.

Based on the high number of joints, a more reliable electrical connection can be ensured, even if one of the joints is not electrically conductive anymore, e.g., due to a material defect, like a crack or the like.

The embodiment of FIG. 19 corresponds to the embodiment of FIG. 18, wherein the tracks 133-1, 133-2 and 133-3 have an ellipsoidal shape/rounded corners instead of a rectangular shape as illustrated in FIG. 18.

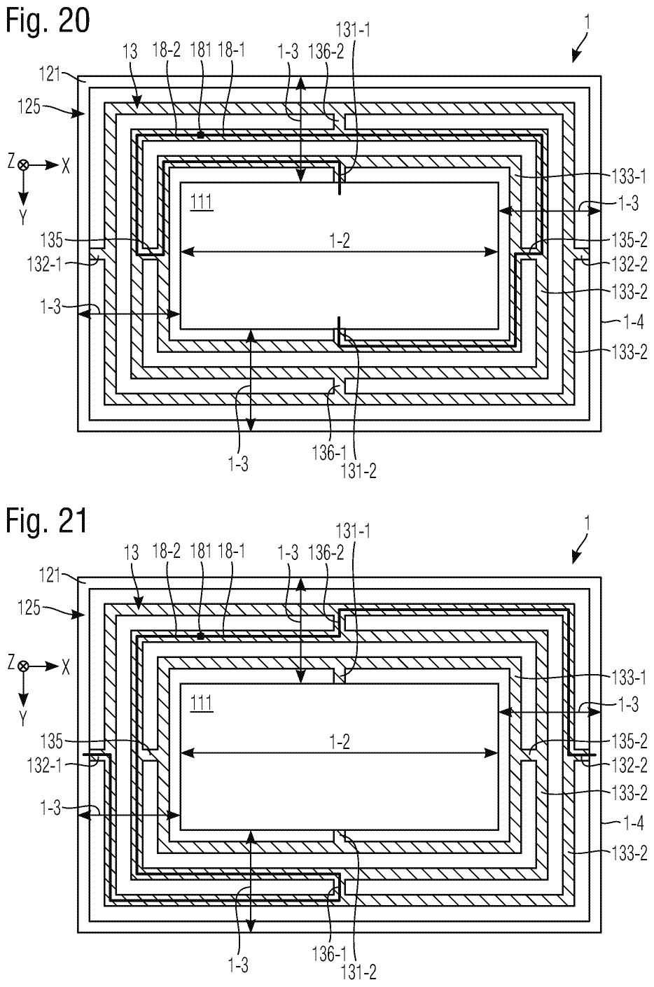

Referring to FIGS. 20 and 21, an effect of the field plate structure 13 illustrated in FIGS. 18 to 24 shall be explained: The field plate structure 13 can be understood as a network of resistive field plates, e.g., the plurality of tracks, (e.g., made of poly-crystalline silicon) that ensures that every point 181 of this network has at least two different continuous electrical connections 18-1, 18-2 to the first potential 111, and at least two different continuous connections 18-3, 18-4 to the second potential 121. Thereby, it is prevented that the electrical connection to one of the potentials 111, 121 is lost when the tracks or joints are interrupted at one location.

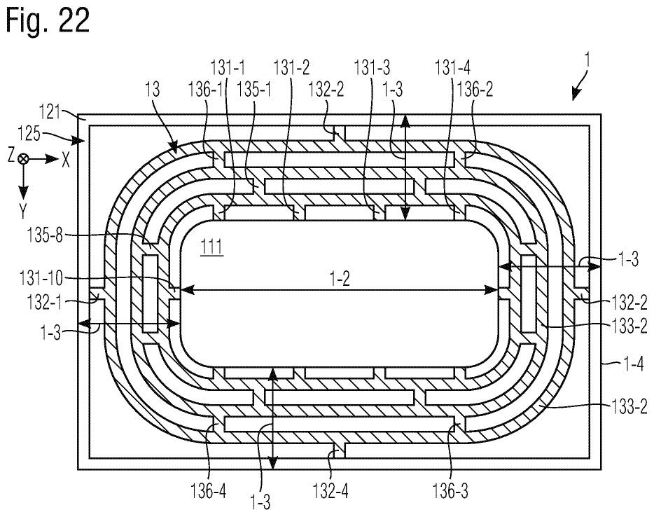

As illustrated in FIG. 22, the reliability can be increased by increasing the number of joints; e.g., in accordance with the embodiment of FIG. 22, ten first joints 131-1 to 131-10 are employed, four second joints 132-1 to 132-4 and 12 third joints 135-1 to 135-8 and 136-1 to 136-4. Not only the reliability can be increased:

E.g., based on the number of joints used to electrically connect the respective track with one of the first and the second electrical potential 111/121 and/or, respectively, with one or two adjacent tracks, the course of the electrical potential within the edge termination region 1-3 may be configured. For example, in FIG. 22, with more joints in the inner part of the edge termination region 1-3 than in the outer part is shown. In this way, the resistance between adjacent tracks can be made smaller in the inner part of the edge termination region 1-3 than in the outer part of the edge termination region 1-3. This may yield a favorable potential distribution in the field-plate network. Another advantage of a network with higher number of joints is that the potential distribution is defined by the distance between the joints 131, 132, 135, 136, and the total resistance of the field plate structure 13 may be designed more or less independently of the chip size (as long as the maximum distance is smaller than the chip dimensions).

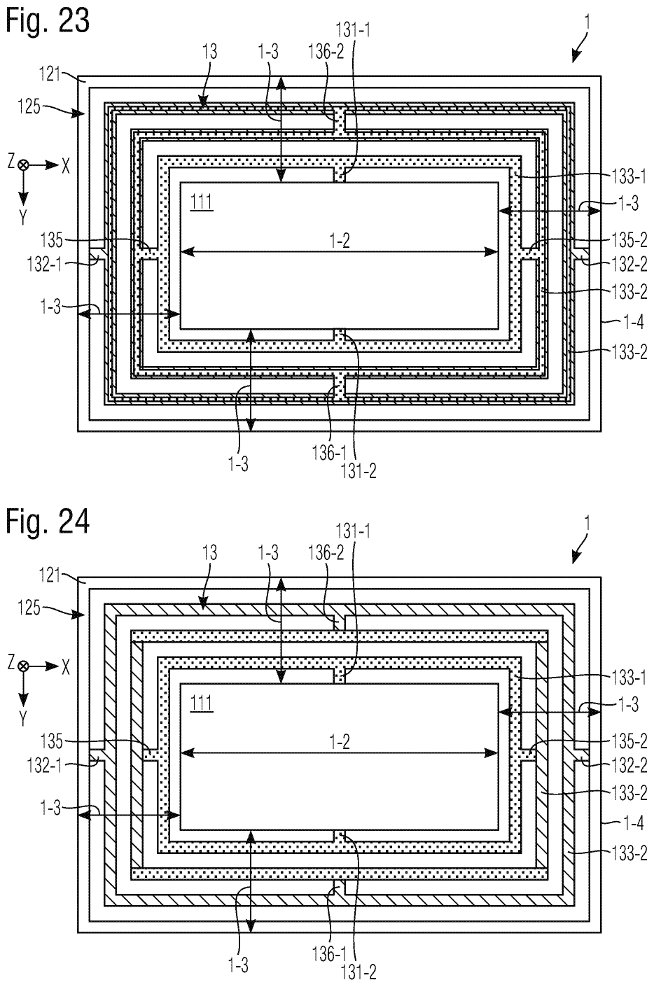

As explained above, there are further ways of configuring the distribution of the electrical potential in the edge termination region 1-3 based on the field plate structure 13. For example, referring to FIGS. 23 and 24, the dopant concentration is comparatively high in dotted regions, and comparatively low in the bold/cross-hatched regions of the tracks 133-1, 133-2 and 133-3. Such dopant concentration profile may be achieved based on a masked implantation.

The features of the embodiments of FIGS. 18 to 24 may be combined with the features of the embodiments of FIGS. 1 to 17 to form yet further embodiments, if not explicitly stated otherwise.

Also presented herein are methods of producing a power semiconductor device having a configuration as a respective one of the embodiments illustrated in FIGS. 18 to 24.

In the above, embodiments pertaining to power semiconductor device, such as MOSFETs, IGBTs, RC IGBTs and derivatives thereof, and corresponding processing methods were explained. For example, these power semiconductor devices are based on silicon (Si). Accordingly, a monocrystalline semiconductor region or layer, e.g., the semiconductor body 10 and its regions/zones, e.g., regions etc. can be a monocrystalline Si-region or Si-layer. In other embodiments, polycrystalline or amorphous silicon may be employed.

It should, however, be understood that the semiconductor body 10 and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising”, “exhibiting” and the like are open ended terms that indicate the presence of stated elements or features, but do not preclude additional elements or features.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A power semiconductor device, comprising:
an active region configured to conduct a load current between a first load terminal and a second load terminal; and
an edge termination region surrounding the active region,
wherein in the edge termination region, a field plate structure is arranged around the active region and comprises at least one electrically conductive track electrically connected to a first potential of the first load terminal at a first joint and, at a second joint, electrically connected to a second potential of the second load terminal,
wherein the at least one electrically conductive track forms at least n crossings,
wherein n is greater 5, with a straight virtual line that extends from the active region towards an edge of the edge termination region,
wherein:
the difference in potential between adjacent two of the n crossings increases in at least 50% of the length of the virtual line; and/or
the difference in potential within, with respect to the active region, the first 20% of the length of virtual line is less than 10% of the total difference in potential along the virtual line.

2. The power semiconductor device of claim 1, wherein the difference in potential within, with respect to the active region, the first 20% of the length of the virtual line is less than half of the difference in potential within the last 20% of the length of the virtual line.

3. The power semiconductor device of claim 1, wherein both the difference in potential within, with respect to the active region, the first 20% of the length of the virtual line, and the difference in potential within, with respect to the active region, the last 20% of the length of the virtual line, are less than the difference in potential within another 20% of the length of the virtual line between the first 20% and the last 20% of the virtual line.

4. The power semiconductor device claim 1, wherein the ohmic resistance between adjacent two of the n crossings increases in at least 50% of the total length of the virtual line.

5. The power semiconductor device of claim 1, wherein the ohmic resistance between adjacent two of the n crossings reaches a maximum within the last 40% or within the last 20% of the length of the virtual line and from there decreases towards the edge.

6. The power semiconductor device of claim 1, wherein the electric conductivity of the at least one track decreases in a portion of the track that forms the crossings in a portion corresponding to at least 50% of the total length of the virtual line.

7. The power semiconductor device of claim 1, wherein the electric conductivity of a respective one of the at least one track along a direction in parallel to the virtual line is substantially constant along an extension of a respective one of the crossings.

8. The power semiconductor device of claim 1, wherein the first joint is arranged in proximity to the active region or, respectively, in the active region, and wherein the second joint is arranged in proximity to the edge or, respectively, at the edge.

9. The power semiconductor device of claim 1, wherein the total horizontal area of the at least one track forms at most 75% of the total horizontal area of the edge termination region.

10. The power semiconductor device of claim 1, wherein the at least one track comprises an electrical resistance per unit length that varies along the pathway of the track from the first joint to the second joint.

11. The power semiconductor device of claim 1, wherein the at least one track comprises at least two first portions and at least two second portions which adjoin each other along the pathway of the track from the first joint to the second joint, wherein the electrical resistance per unit length of the at least one track has a first value in the first portions and a second value in the second portions.

12. The power semiconductor device of claim 1, wherein the at least one track has a width along a direction perpendicular to the pathway of the track from the first joint to the second joint, the width defining the extension of the respective crossing, wherein a distance between two adjacent crossings increases along at least a part of the virtual line.

13. The power semiconductor device of claim 1, wherein the at least one track comprises a polycrystalline doped semiconductor material, wherein the dopant concentration of the polycrystalline doped semiconductor material varies along the pathway of the track from the first joint to the second joint, or wherein the dopant concentration of the polycrystalline doped semiconductor material is substantially constant along the pathway of the track from the first joint to the second joint.

14. The power semiconductor device of claim 1, wherein the at least one track has a width along a direction perpendicular to the pathway of the track from the first joint to the second joint, the width defining the extension of the respective crossing, wherein a distance between arbitrary two adjacent crossings along the virtual line amounts to at most half of the average of the extensions of the respective adjacent crossings.

15. The power semiconductor device of claim 1, wherein the second joint laterally overlaps with a semiconductor well region of a first conductivity type arranged in a semiconductor body of the power semiconductor device, wherein the first joint laterally overlaps with a semiconductor body region of a second conductivity type arranged in the semiconductor body.

16. The power semiconductor device of claim 15, wherein a first semiconductor region extends from the semiconductor well region towards the active region and laterally overlaps with at least the last crossing.

17. The power semiconductor device of claim 1, wherein a second semiconductor region extends from the semiconductor body region towards the edge and laterally overlaps with at least the 50% of the virtual line.

18. The power semiconductor device of claim 1, wherein the field plate structure arranged around the active region comprises two or more electrically conductive tracks arranged in an interleaved manner with respect to each other.

19. The power semiconductor device of claim 18, wherein at least two of the two or more tracks are electrically connected to the first potential of the first load terminal based on separate first joints, wherein the at least two tracks merge into one track in a central portion of the edge termination region.

20. The power semiconductor device of claim 1, wherein the total resistance measured between the first joint and the second joint is at least 100, or at least 1000 times as great as a lowest sheet resistance of the material of the at least one track.

21. The power semiconductor device of claim 1, wherein the field plate structure is coil-shaped.

22. The power semiconductor device of claim 1, wherein the straight virtual line is perpendicular to the edge.

23. A method of producing a power semiconductor device, the method comprising:
forming an active region configured to conduct a load current between a first load terminal and a second load terminal; and
forming an edge termination region surrounding the active region,
wherein in the edge termination region, a field plate structure is arranged around the active region and comprises at least one electrically conductive track electrically connected to a first potential of the first load terminal at a first joint and, at a second joint, electrically connected to a second potential of the second load terminal,
wherein the at least one electrically conductive track forms at least n crossings,
wherein n is greater 5, with a straight virtual line that extends from the active region towards an edge of the edge termination region,
wherein the difference in potential between adjacent two of the n crossings increases in at least 50% of the length of the virtual line, and/or the difference in potential within, with respect to the active region, the first 20% of the length of virtual line is less than 10% of the total difference in potential along the virtual line.

24. A power semiconductor device, comprising:
an active region configured to conduct a load current between a first load terminal and a second load terminal; and
an edge termination region surrounding the active region,
wherein in the edge termination region, a field plate structure is arranged around the active region and comprises a plurality of conductive tracks electrically connected to a first potential of the first load terminal and electrically connected to a second potential of the second load terminal,
wherein each track surrounds the active region,
wherein the tracks are spaced apart from each other along a direction from the active region to an edge of the edge termination region,
wherein the innermost track is electrically connected to the first potential of the first load terminal based on at least two separately arranged first joints,
wherein the outermost track is electrically connected to the second potential of the second load terminal based on at least two separately arranged second joints,
wherein the tracks of each pair of adjacent tracks are electrically connected with each other based on at least two separately arranged third joints.
